(19) United States
(12) Patent Application Publication
(10) Pub. No.: US 2026/0177763 A1
(43) Pub. Date: Jun. 25, 2026

(54) WAVELENGTH DIVISIONAL MULTIPLEXING THROUGH GRATING COUPLER ARRAY

(71) Applicant: Taiwan Semiconductor Manufacturing Co., Ltd., Hsinchu (TW)

(72) Inventors: Chia-Han Tsou, Hsinchu (TW); Ming-Fa Chen, Taichung City (TW)

(21) Appl. No.: 19/077,719

(22) Filed: Mar. 12, 2025

Related U.S. Application Data
(60) Provisional application No. 63/738,012, filed on Dec. 23, 2024.

(51) Int. Cl. G02B 6/42; H01L 25/16

(52) U.S. Cl. CPC G02B 6/4215; G02B 6/4214; G02B 6/4244; G02B 6/4283; H10W 90/00

(57) ABSTRACT

A method includes forming a photonic engine. The formation of the photonic engine includes receiving a photonic die including a plurality of grating couplers, and a plurality of micro lenses attached to the photonic die. The plurality of grating couplers and the plurality of micro lenses are configured to be optically inter-coupled in a one-to-one correspondence. A fiber assembly unit is attached to the photonic engine. The fiber assembly unit includes an optical fiber, and a laser merging unit configured to optically inter-couple the plurality of micro lenses and the optical fiber.

### PRIORITY CLAIM AND CROSS-REFERENCE

This application claims the benefit of the following provisionally filed U.S. Patent application: Application No. 63/738,012, filed on Dec. 23, 2024, and entitled “Si ulens and Fiber Array Unit in COUPE,” which application is hereby incorporated herein by reference.

### BACKGROUND

Electrical signaling and processing are one of techniques for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7 illustrate the views of intermediate stages in the formation of a package including a photonic die in accordance with some embodiments.

FIG. 8 illustrates a package with laser beams propagated through a plurality of micro-lenses and a plurality of grating couplers in accordance with some embodiments.

FIG. 9 illustrates the optical coupling of a grating coupler array, a micro-lens array, and a row of optical fibers in accordance with some embodiments.

FIG. 10 illustrates the merging of a plurality of laser beams having different wavelengths into an optical fiber (or splitting a laser beam into a plurality of laser beams having different wavelengths) in accordance with some embodiments.

FIGS. 11A and 11B illustrate the patterns of bandpass filters in accordance with some embodiments.

FIGS. 12A and 12B illustrate the patterns of reflectors in accordance with some embodiments.

FIG. 13 illustrates the merging of a plurality of laser beams having different wavelengths into two optical fibers (or splitting two laser beams into a plurality of laser beams having different wavelengths) in accordance with some embodiments.

FIG. 14 illustrates schematic view of a function of a package including a photonic die in accordance with some embodiments.

FIG. 15 illustrates a process flow for forming a photonic package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including a photonic engine) configured for being used in Wavelength Divisional Multiplexing (WDM) and the method of forming the same are provided. In accordance with some embodiments of the present disclosure, the photonic engine includes a plurality of grating couplers forming a grating coupler array, and a plurality of micro-lenses forming a micro-lens array. A plurality of laser beams with different wavelengths may be projected out through a column of grating couplers, and projected to a corresponding column of micro-lenses. The plurality of laser beams are merged into a same optical fiber. Similarly, the laser transmitted in an optical fiber may be multiplexed as a plurality of laser beams with different wavelengths. The plurality of laser beams may be projected to a corresponding column of micro-lenses, and further projected to a corresponding column of grating couplers.

The plurality of grating couplers in the same column have different structures suit to the wavelengths of the corresponding laser beams. Accordingly, through the multiple grating couplers, the combined bandwidth of the multiple wavelengths is increased.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

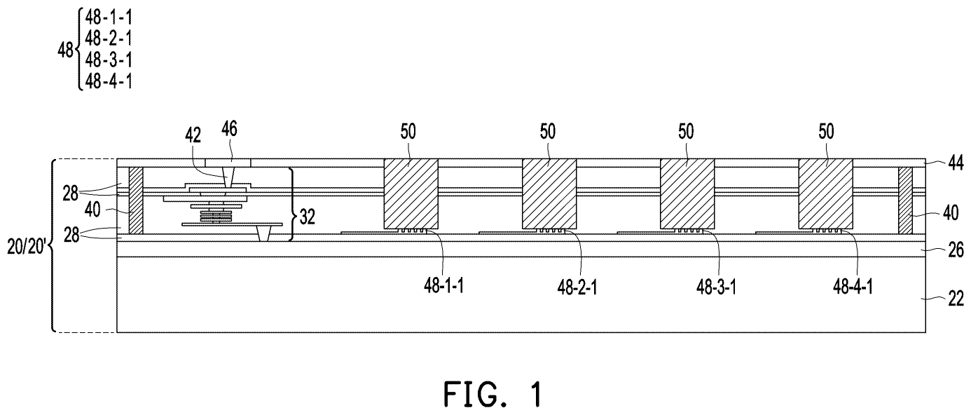

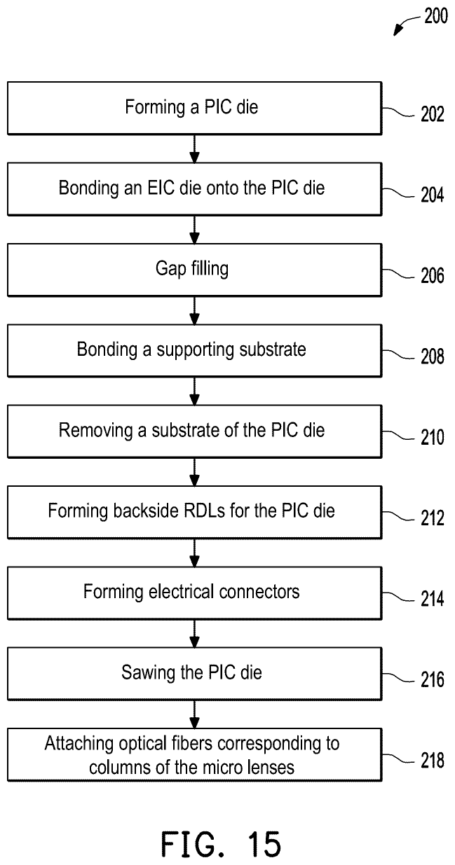

FIGS. 1 through 7 illustrate the cross-sectional views of intermediate stages in the formation of a photonic package in accordance with some embodiments of the present disclosure. The corresponding processes are also reflected schematically in the process flow shown in FIG. 15.

Referring to FIG. 1, photonic die 20′ is formed. The respective process is shown as process 202 in the process flow 200 as shown in FIG. 15. In accordance with some embodiments, photonic die 20′ is a part of an unsawed photonic wafer 20, which includes a plurality of photonic dies 20′ that are identical. Photonic die 20′ is alternatively referred to as Photonic Integrated circuit (PIC) die 20′.

Photonic die 20′ may include semiconductor substrate 22, which may be a silicon substrate in accordance with some embodiments. Dielectric layer 26 is formed over semiconductor substrate 22. In accordance with some embodiments, dielectric layer 26 is an etch stop layer that is used in the subsequent formation of conductive features. The material of dielectric layer 26 may comprise silicon nitride, silicon oxynitride, silicon carbide, silicon oxycarbide, silicon oxide, or the like.

In accordance with some embodiments, photonic die 20′ may include integrated circuit devices (not shown) formed at a surface of semiconductor substrate 22. The integrated circuit devices (if formed) are used to support the functionality of the photonic die in accordance with some embodiments. The integrated circuit devices may include active devices such as transistors and/or diodes. The integrated circuit devices may also include passive devices such as capacitors, resistors, or the like. In accordance with alternative embodiments, no integrated circuit devices are formed in photonic die 20′.

Photonic die 20′ may include photonic devices such as waveguides, grating couplers, modulators, and/or the like. The waveguides may include silicon waveguides and/or silicon nitride waveguides. In accordance with some embodiments, dielectric layers 28 are formed, and may include silicon oxide, silicon oxynitride, aluminum oxide, aluminum nitride, or the like.

In accordance with some embodiments, dielectric layers 28 are formed over grating couplers 48. Dielectric layers 28 may comprise light-transparent and low-loss dielectric materials such as silicon oxide. The plurality of dielectric layers 28 may include Inter-Metal Dielectrics (IMDs), which may include a low-k dielectric material(s) such as porous silicon oxynitride. There may also be etch stop layers formed between the low-k dielectric materials. The etch stop layer may comprise AlN, AlO, SiON, or the like, or multi-layers thereof.

Interconnect structure 32 is formed, which may include metal vias and metal lines and the respective portions of dielectric layers 28. The metal vias and metal lines may be formed through single damascene processes and/or dual damascene processes. Interconnect structure 32 may further include aluminum pads (which comprise aluminum copper), dielectric passivation layers, and the like. Dielectric layers 28 may also comprise an organic dielectric layer comprising an organic dielectric material, which may be a polymer such as polyimide, polybenzoxazole (PBO), benzocyclobutene (BCB), or the like.

In accordance with some embodiments, the wafer 20 (and the photonic die 20′ therein) includes a device region and a ring region surrounding the device region. The interconnect structure 32 is disposed over the device region. A seal ring structure 40 is formed in a periphery region of photonic die 20′ and surrounding the interconnect structure. The device region may comprise a plurality of transistors (not shown) at the surface of and extending into substrate 22. The plurality of transistors are functionally connected by way of metal features in the interconnect structure.

The seal ring structure 40 comprises metal features extending continuously around the interconnect structure, which metal features are interconnected to form solid walls with no openings therein. The seal ring structure 40 comprises a plurality of conductive lines and conductive vias (not shown individually). The conductive lines and conductive vias are formed of a material including copper at an atomic percentage greater than 80% (in some embodiments, greater than about 90% or greater than about 95%).

Conductive via 42 is formed as a part of the interconnect structure 32. Conductive via 42 may comprise a conductive material such as copper, tungsten, or the like, and may or may not include a diffusion barrier formed of Ti, TiN, Ta, TaN, or the like, or multi-layers. Conductive via 42 may land on a metal pad in accordance with some embodiments.

Bond layer 44 is formed over Conductive via 42. In accordance with some embodiments, bond layer 44 may have a multi-layer structure or a single layer structure. The material of bond layer 44 may comprise a silicon-containing dielectric material such as silicon oxide, silicon nitride, silicon oxynitride, silicon carbide, silicon oxy-carbide, or combinations thereof.

Bond pads 46 are formed in dielectric layers 44. In accordance with some embodiments, bond pads 46 may comprise copper, and may comprise a diffusion barrier, such as Ti, TiN, Ta, TaN, or the like. The formation process may include etching bond layer 44 to form openings, depositing a conductive material to fill the openings, and performing a planarization process to remove the portions of the conductive material over bond layer 44.

In accordance with some embodiments, the photonic devices in the photonic die 20′ may include a plurality of grating couplers 48, which may be formed of silicon in accordance with some embodiments. For example, a silicon layer may be formed on dielectric layer 26, for example, by bonding a silicon layer to dielectric layer 26, followed by the patterning of the silicon layer through etching, so that waveguides, grating couplers, and the like are formed.

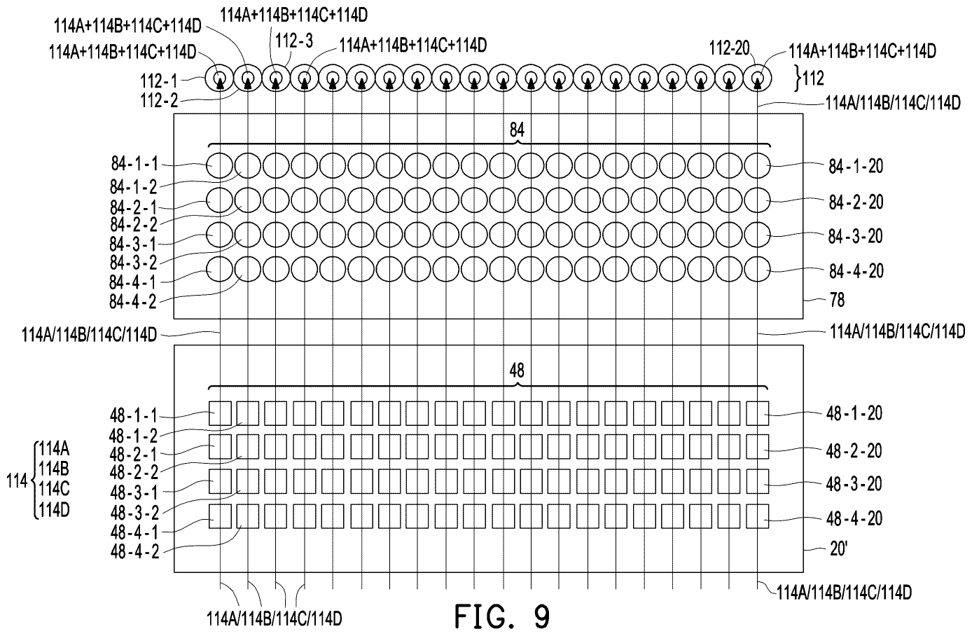

The plurality of grating couplers 48 may include at least one column of (as shown in FIG. 9), and possibly a plurality of columns of, grating couplers 48, which will be formed as an array. FIG. 1 illustrates an example column of grating couplers 48, which are denoted as grating couplers 48-1-1, 48-2-1, 48-3-1, and 48-4-1. In accordance with some embodiments, grating couplers 48-1-1, 48-2-1, 48-3-1, and 48-4-1 are suited to receive or project the laser beams with different wavelengths, and the corresponding wavelengths are referred to as the characteristic wavelengths of the corresponding grating couplers 48. When working with laser beams having wavelengths same as the characteristic wavelength, a grating coupler has lowest loss. When working with laser beams having wavelengths greater than or lower than the characteristic wavelength, the grating coupler has higher loss. Accordingly, the structures of grating couplers 48-1-1, 48-2-1, 48-3-1, and 48-4-1 are different from each other.

In accordance with some embodiments, transparent dielectric regions 50 are formed over grating couplers 48. The formation process may include etching dielectric layers 28 to form openings that overlap grating couplers 48, filling the openings with a dielectric material having good transparency, and performing a planarization process such as a Chemical Mechanical Polish (CMP) process or a mechanical polish process. An example material of the transparent dielectric regions 50 may comprise silicon oxide.

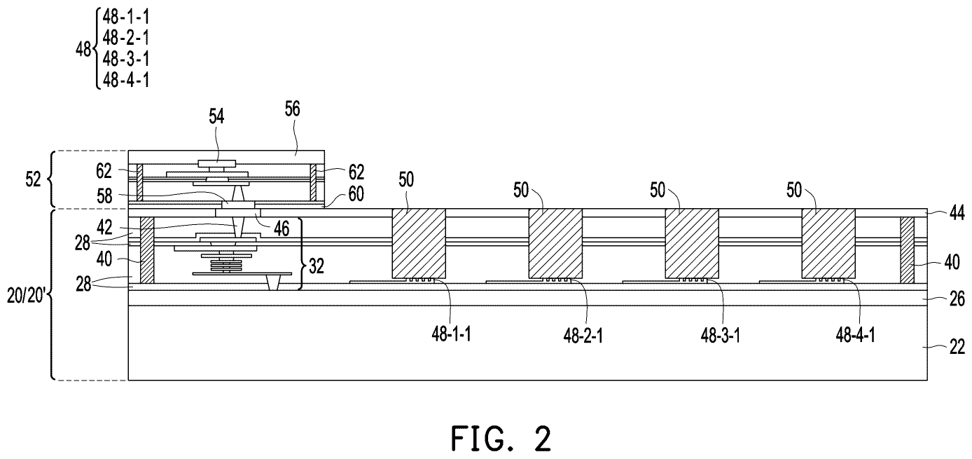

Referring to FIG. 2, device die 52, which may be an Electronic Integrated circuit (EIC) die 52, is bonded to the photonic die 20′. The respective process is shown as process 204 in the process flow 200 as shown in FIG. 15. In accordance with some embodiments, EIC die 52 includes a semiconductor substrate 56 (which may be a silicon substrate) and the integrated circuits 54 formed at a surface of semiconductor substrate 56.

The integrated circuits 54 may include active devices such as transistors, diodes, or the like, and may or may not include passive devices such as capacitors, inductors, resistors, or the like. For example, a transistor in the active devices 54 may include source and drain regions, a gate dielectric, a gate electrode, and gate spacers in accordance with some embodiments.

EIC die 52 further includes dielectric layer 60 as a bond layer, with bond pads 58 being formed in bond layer 60. In accordance with some embodiments, EIC die 52 may include seal ring 62 therein, which forms a full ring (when viewed in a bottom view of EIC die 52) that is proximate the peripheral regions of EIC die 52. EIC die 52 may include an interconnect structure, which includes dielectric layers, and metal vias and metal lines in the dielectric layers. The dielectric layers may include low-k dielectric layers, which may be formed of carbon-containing dielectric layers.

In accordance with some embodiments, the EIC die 52 includes a device region and a ring region surrounding the device region. Seal ring structure 62 is formed in a periphery region and surrounding the interconnect structure and the device region.

The seal ring structure 62 comprises metal features extending continuously around the interconnect structure, wherein the metal features are interconnected as a solid wall with not openings therein. The seal ring structure 62 comprises a plurality of conductive lines and conductive vias (not shown individually). The conductive lines and conductive vias are formed of a material including copper at an atomic percentage greater than 80% (in some embodiments, greater than about 90% or greater than about 95%.)

The bonding between the photonic die 20′ and the EIC die 52 may include metal-to-metal direct bonding, solder bonding, or hybrid bonding that includes both of metal-to-metal direct bonding and fusion bonding. For example, the bond layer 60 may be bonded to bond layer 44 through fusion bonding.

In accordance with some embodiments, the EIC die 52 may include integrated circuits 54 for communicating with the photonic die 20′, such as the circuits for controlling the operation of the photonic die 20′. For example, the integrated circuits 54 may include controllers, drivers, amplifiers, the like, or combinations thereof. the EIC die 52 may also include a CPU. In accordance with some embodiments, the EIC die 52 includes the circuits for processing electrical signals received from (or sent to) the photonic die 20′. The EIC die 52 may also control high-frequency signaling of the photonic die 20′ according to electrical signals (digital or analog) received from another device or die. In accordance with some embodiments, the EIC die 52 may include a circuit that provides Serializer/Deserializer (SerDes) functionality. In this manner, the EIC may act as a part of an I/O interface between optical signals and electrical signals.

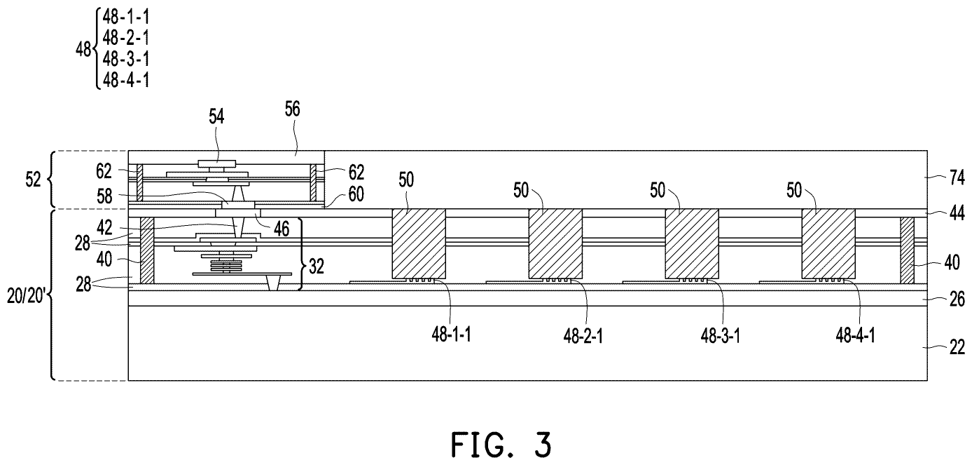

It is appreciated that the processes as illustrated in FIGS. 1 and 2 are at wafer level, wherein a plurality of EIC dies 52 may be bonded to a plurality of photonic dies 20′ of photonic wafer 20 in accordance with some embodiments. FIG. 3 illustrates a gap-fill process in accordance with some embodiments, wherein the gaps between neighboring EIC dies 52 are filled to form dielectric regions 74 that encircle the EIC dies 52. The respective process is shown as process 206 in the process flow 200 as shown in FIG. 15. Dielectric regions 74 are also referred to as gap-fill regions 74.

The gap-fill region 74 may include a dielectric layer, and may or may not include a dielectric barrier under the dielectric layer. The formation of the dielectric barrier may include a conformal deposition process such as ALD, CVD, or the like. The material of dielectric barrier is selected to have good adhesion ability for adhering on EIC dies 52. In accordance with some embodiments, the dielectric barrier is formed of or comprise silicon nitride, silicon carbo-nitride, silicon oxynitride, silicon carbide, or the like. The dielectric layer, which may be light-transparent, may include silicon oxide, silicon oxynitride, or the like.

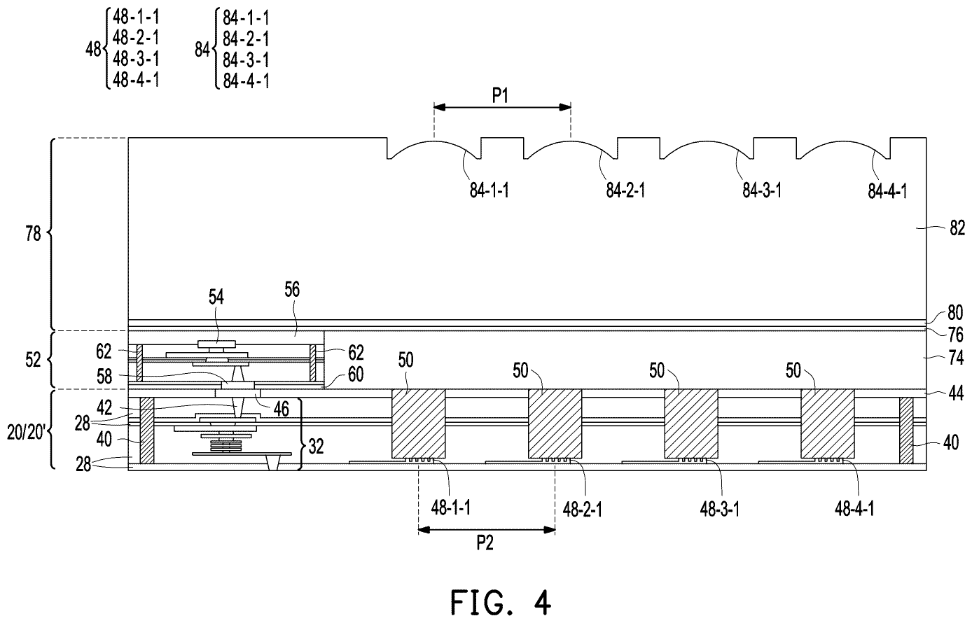

Next, referring to FIG. 4, bond layer 76 is deposited on gap-fill regions 74 and EIC dies 52 through a deposition process. In accordance with some embodiments, bond layer 76 is formed of or comprise silicon oxide, silicon oxynitride, or the like.

Supporting substrate 78 (which may be a wafer) is bonded to bond layer 76. The respective process is shown as process 208 in the process flow 200 as shown in FIG. 15. In accordance with some embodiments, supporting substrate 78 includes bond layer 80, and silicon substrate 82 attached to bond layer 76. Bond layer 80 may be formed of or comprise a silicon-containing dielectric material such as silicon oxide, silicon oxynitride, silicon carbo-nitride, or the like. The bonding may include fusion bonding, with bond layer 80 being bonded to bond layer 76.

In accordance with some embodiments, supporting substrate 78 includes micro lenses 84, which are formed as a part of silicon substrate 82, for example, by etching silicon substrate 82. Supporting substrate 78 may further include a protection layer (not shown), an anti-reflective coating (ARC), or the like formed on silicon substrate 82. In accordance with some embodiments, the pitch P1 of micro lenses 84 is the same as the pitch P2 of grating couplers 48. For example, the pitches P1 and P2 may be in the range between about 100 μm and about 100 μm. In accordance with some embodiments, micro lenses 84 have the same count as grating couplers 48. Micro lenses 84 may be formed as a micro lens array, which has the same number of rows and same number of columns as the grating coupler array 48.

Next, the semiconductor substrate 22 (FIG. 3) is removed. The respective process is shown as process 210 in the process flow 200 as shown in FIG. 15. The removal process may include a CMP process, a mechanical grinding process, or the like. Accordingly, dielectric layer 26 is exposed. Dielectric layer 26 may be removed or may be thinned. In accordance with alternative embodiments in which photonic die 20′ includes active devices, the semiconductor substrate 22 may remain un-removed.

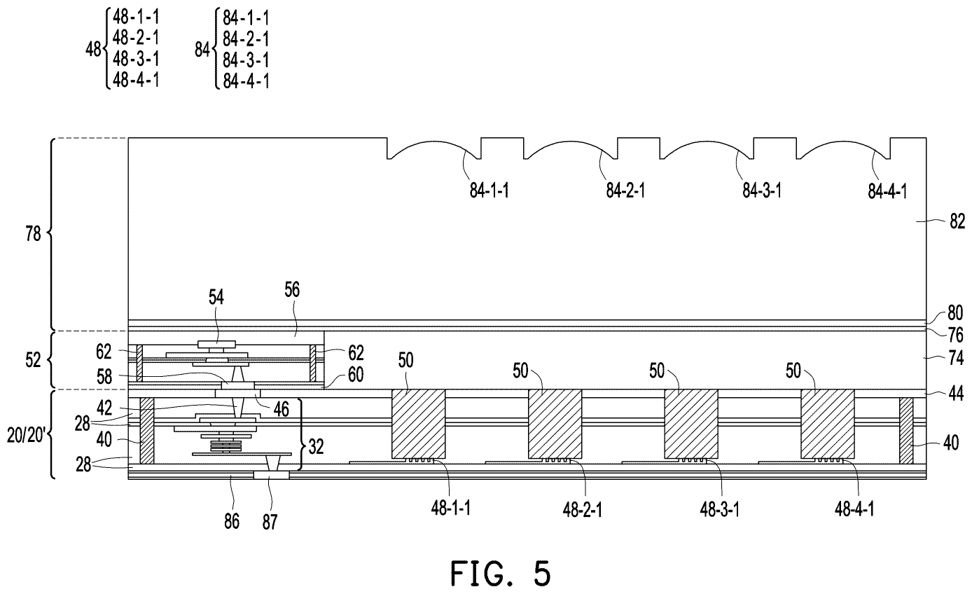

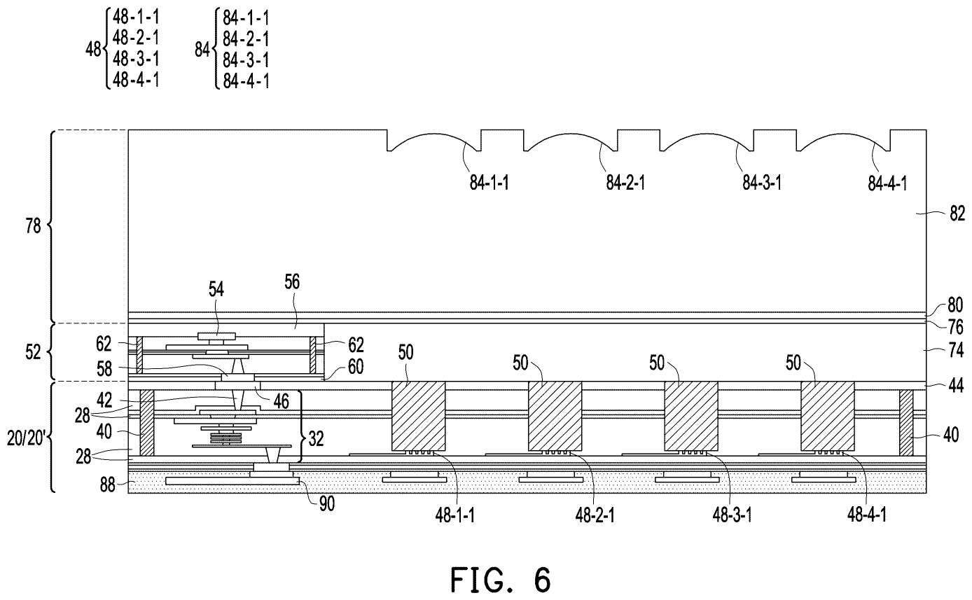

In subsequent processes, as shown in FIG. 5, dielectric layer 86 and metal pads 87 are formed. Next, referring to FIG. 6, dielectric layers 88 and redistribution lines (RDLs) 90 are formed. The respective process is shown as process 212 in the process flow 200 as shown in FIG. 15. Dielectric layers 88 may include inorganic dielectric materials such as silicon oxide, silicon nitride, or the like, and/or organic dielectric materials such as polymers. The polymers may include polyimide, PBO, BCB, or the like.

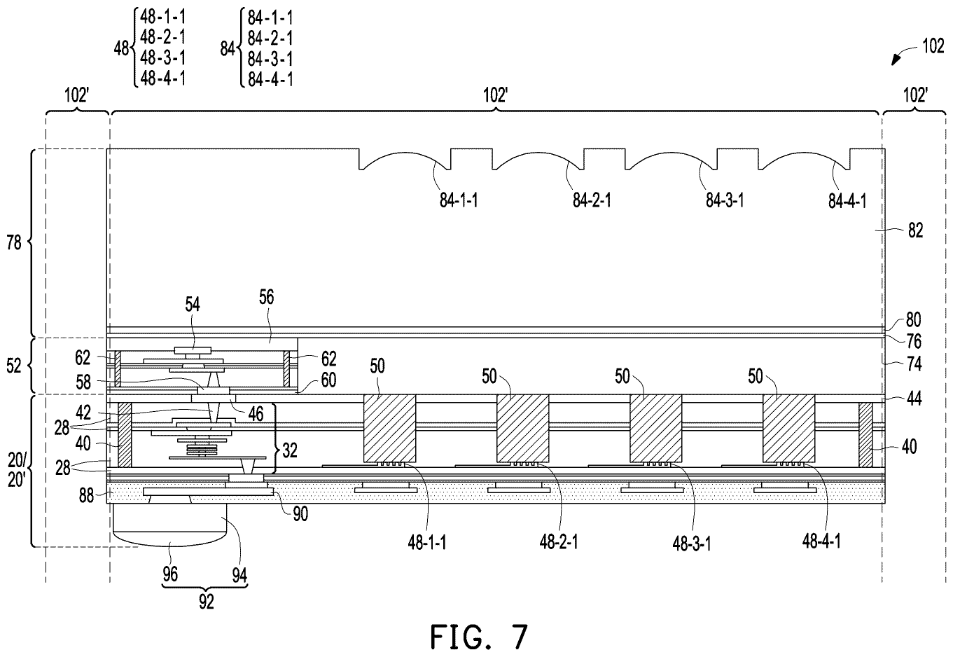

Referring to FIG. 7, more conductive features including electrical connectors 92 may are formed. In accordance with some embodiments, electrical connectors 92 may include metal pillars 94 and solder regions 96. The respective process is shown as process 214 in the process flow 200 as shown in FIG. 15. Reconstructed wafer 102 is thus formed.

In a subsequent process, a sawing process (also referred to as a singulation process) is performed to saw reconstructed wafer 102 and to form a plurality of optical engines 102′, which are also referred to as photonic engines or photonic packages. The respective process is shown as process 216 in the process flow 200 as shown in FIG. 15. The plurality of optical engines 102′ are identical to each other. Each of the plurality of optical engines 102′ may include a photonic die 20′, an EIC die 52, and a piece of supporting substrate 78, which is sawed from the wafer-level supporting substrate 78.

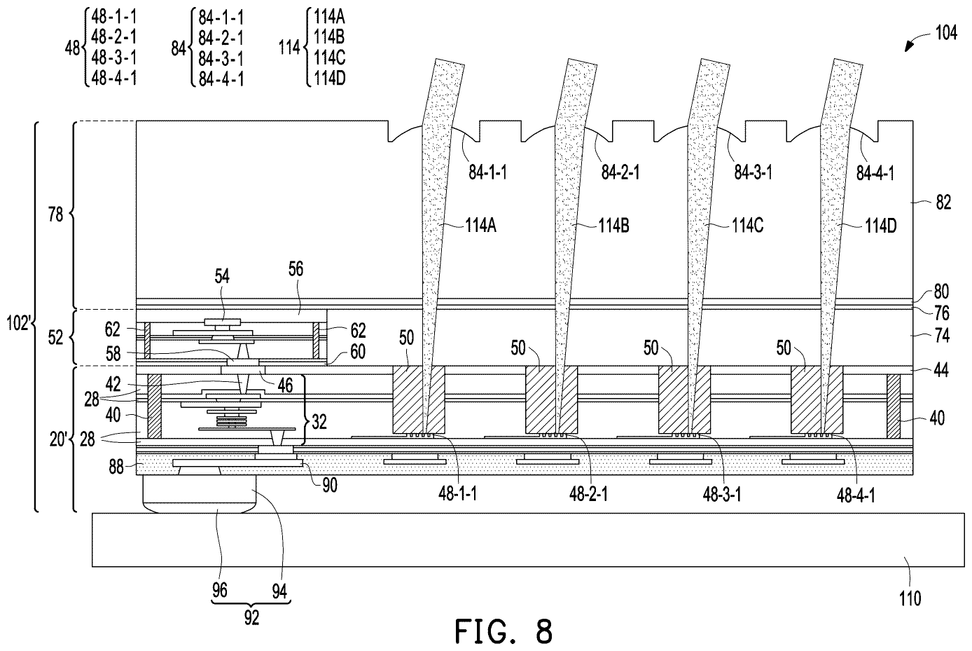

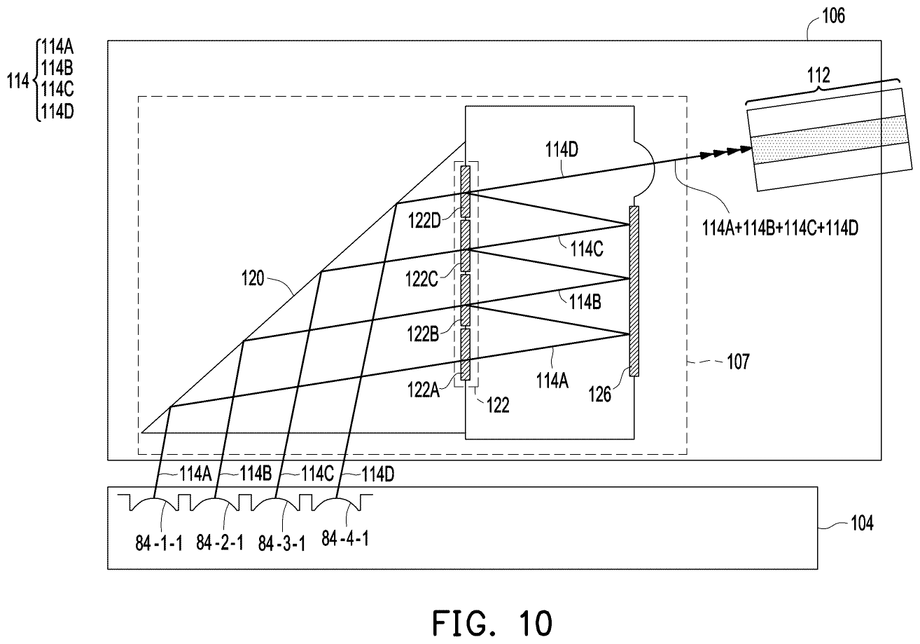

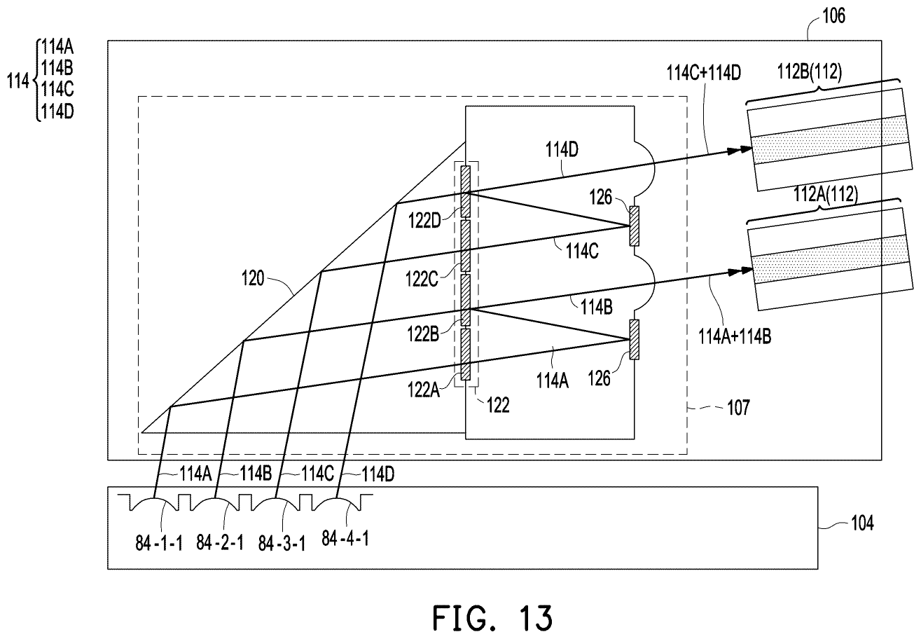

FIG. 8 illustrates the usage of photonic engine 102′ in accordance with some embodiments. Photonic engine 102′ may be bonded to an underlying package component 110 to form package 104. The respective process is shown as process 218 in the process flow 200 as shown in FIG. 15. The underlying package component 110 may include an interposer, a package substrate, a printed circuit board, or the like. A fiber Assembly Unit (FAU) 106 (not shown in FIG. 8, referring to FIG. 10 or FIG. 13) is attached to the photonic engine 102′. An optical fiber 112 (FIG. 10 or FIG. 13) is attached to the fiber assembly unit 106.

In the following discussion of an example usage of the photonic package 100′, it is assumed that laser beams 114 (FIG. 8) are generated in response to the electrical signals in EIC die 50. Optical signals are generated as laser beams 114 (including laser beams 114A, 114B, 114C, and 114D as an example), and are projected out of grating couplers 48. The laser beams 114 pass through micro lenses 84, and are projected into an optical fiber 112 as shown in FIG. 10 or FIG. 13.

In accordance with alternative embodiments, the laser beams 114 propagate in an inversed direction. For example, a laser beam is projected out of an optical fiber 112 (FIG. 10 or FIG. 13), and split into a plurality of laser beams 114 having different wavelengths. The laser beams 114 pass through micro lenses 84, and are received by grating couplers 48, and are further processed by photonic die 20′ and EIC die 52.

In accordance with some embodiments, the laser beams 114 (such as laser beams 114A, 114B, 114C, and 114D) have different wavelengths. For example, when Coarse Wavelength Divisional Multiplexing (CWDM) is used, the wavelength pitch may be 20 nm. The wavelengths of the CWDM may include 1,290 nm, 1,310 nm, and 1,330 nm, which have the wavelength pitch of 20 nm. The grating couplers 48-1-1, 48-2-1, and 48-3-1 thus have the structure configured to work with the wavelengths of the CWDM such as 1,290 nm, 1,310 nm, and 1,330 nm, respectively.

It is realized that a single grating coupler 48 may not be able to support the wide bandwidth of WDMs such as CWDM, Local area network WDM (LWDM, with the wavelength pitch of 4.5 nm), Dense Wavelength Divisional Multiplexing (DWDM, with the wavelength pitch of 0.8 nm), or the like. The plurality of the grating couplers 48, by having different structures and different characteristic wavelengths, however, may collectively support the wide waveband of the WDMs.

FIG. 9 illustrates a schematic view showing the operation and the relationship of grating couplers 48, micro lenses 84, optical fibers 112, and laser beams 114 in accordance with some example embodiments. The grating couplers 48 and micro lenses 84 are arranged as a grating coupler array (also denoted as 48) and a micro lens array (also denoted as 84), respectively. In the illustrated example embodiment, each of the grating coupler array 48 and micro lens array 84 has four rows and 20 columns. In other embodiments, the rows may have any number, for example, in the range between 2 and 16. The columns may have any number, for example, in the range between 1 and 128.

In the subsequent discussion, the specific grating coupler and micro lens may be referred to using three numbers separated by two “−” signs. The first number, which may be 48 or 84, represents whether it is a grating coupler or a micro lens. The second number, which is following the first “−” sign, represents the corresponding row number. The third number, which is following the second “−” sign, represents the corresponding column number. For example, grating coupler 48-1-1 is in row 1 and column 1. Grating coupler 48-2-1 is in row 2 and column 1. Grating coupler 48-1-20 is in row 1 and column 2o.

There is one row of optical fibers 112 illustrated. The specific optical fiber may be referred to using two numbers separated by a “−” sign. The first number 112 represents that it is an optical fiber, and the second number following the “−” sign represents its corresponding column number. In accordance with some embodiments, the grating coupler 48, the micro lenses 84, and the optical fibers have a same number (count) of columns, and their columns have a one-to-one correspondence, as will be discussed in detail.

In accordance with some embodiments, the grating couplers 48 in a same row have a same structure, and have the same characteristic wavelength. The structure in each row of grating couplers 48 is different from the structures of the grating couplers 48 in other rows. The characteristic wavelength in each row of grating couplers 48 is different from the characteristic wavelengths of grating couplers 48 in other rows.

For example, grating couplers 48-1-1, 48-1-2 ... through 48-1-20 have the same structure and the same characteristic wavelength (such as 1,290 nm). Grating couplers 48-2-1, 48-2-2 . . . through 48-2-20 have the same structure and the same characteristic wavelength (such as 1,310 nm). Grating couplers 48-3-1, 48-3-2 ... through 48-3-20 have the same structure and the same characteristic wavelength (such as 1,330 nm). Accordingly, the grating couplers 48 in each column of grating couplers collectively cover (and may extend beyond when the fourth row is used) the bandwidth of the CWDM, which covers 1,290 nm, 1,310 nm, and 1,330 nm.

Referring to the first column of grating couplers 48 as an example, four laser beams 114, which include laser beams 114A, 114B, 114C, and 114D, are transported to grating couplers 48-1-1, 48-2-1, 48-3-1, and 48-4-1, respectively, through waveguides in the photonic die 20′. The laser beams 114A, 114B, 114C, and 114D are physically separated laser beams, and are denoted as laser beams 114A/114B/114C/114D as shown in FIG. 9. The “/” sign represents that the laser beams 114A, 114B, 114C, and 114D are separate laser beams, as shown in FIG. 8.

The laser beams 114A, 114B, 114C, and 114D, after projected out of the grating couplers 48-1-1, 48-2-1, 48-3-1, and 48-4-1, respectively, are projected to micro lenses 84-1-1, 84-2-1, 84-3-1, and 84-4-1, respectively, with a one-to-one correspondence. The laser beam projected into, and projected out of, micro lenses 84-1-1, 84-2-1, 84-3-1, and 84-4-1 are thus also denoted as laser beams 114A/114B/114C/114D to represent that these laser beams are still separate laser beams, as shown in FIGS. 8 and 10.

The laser beams 114A/114B/114C/114D corresponding to the first columns of grating couplers 48 and the first column of micro lenses 84 are merged into the optical fiber 112-1. Accordingly, the laser beams transported by optical fiber 112-1 is denoted as (114A+114B+114C+114D), wherein the “+” sign represents that these laser beams are merged as one laser beam. The first column of grating couplers 48, the first column of grating couplers 84, and the first optical fiber 112 are referred to as being optically inter-coupled.

As shown in FIG. 9, additional laser beams 114A, 114B, 114C, and 114D are transported to the second column of grating couplers 48-1-2, 48-2-2, 48-3-2, and 48-4-2, respectively. The laser beams 114A, 114B, 114C, and 114D transported to the second column of grating couplers 48-1-2, 48-2-2, 48-3-2, and 48-4-2 may carry different optical signals than the corresponding laser beams 114A, 114B, 114C, and 114D transported through the first column of grating couplers 48-1-1, 48-2-1, 48-3-1, and 48-4-1, respectively. Similarly, the additional laser beams 114A, 114B, 114C, and 114D are projected to the second column of micro lenses 84-1-2, 84-2-2, 84-3-2, and 84-4-2, respectively, and are merged into the second optical fiber 112-2. The second column of grating couplers 48, the second column of grating couplers 84, and the second optical fiber 112 are referred to as being optically inter-coupled.

The function of the rest of the columns of the grating coupler 48, micro lenses 84, optical fibers 112 and the corresponding laser beams 114 are similar to, and may be realized from the preceding discussion. Accordingly, in the illustrated example, there may be 4×20 optical signals (which may be different from each other) merged into 20 optical fibers 112. By expanding the number of columns and the number of rows, the number of simultaneously transported optical signals may be further increased. Since optical signals transported by the optical fibers 112 are handled by different grating couplers that are configured to handle different wavelengths, by combining the function of grating couplers 48 in the same column, the bandwidth of the optical signals may be increased without limited by the bandwidth limitation of individual grating couplers.

FIG. 10 illustrates the attachment of Fiber Assembly Unit (FAU) 106 to package 104 and photonic engine 102′. FAU 106 includes a laser merging unit 107 therein, which is configured to merge parallel laser beams into a single laser beam. FIG. 10 further illustrates the operation of the laser beams 114A, 114B, 114C, and 114D projected out of the same column of micro lenses 114, which may be the first-column micro lenses 84-1-1, 84-2-1, 84-3-1, and 84-4-1 as an example. The laser beams 114A, 114B, 114C, and 114D are parallel to each other, and are reflected by reflector 120. The reflected laser beams are projected to bandpass filters (or bandpass filter portions) 122A, 122B, 122C, and 122D, which are parts of the bandpass filter 122.

The bandpass filters 122A, 122B, 122C, and 122D are configured to allow the laser beams 114A, 114B, 114C, and 114D, respectively, to pass through, and are configured to block the rest of the laser beams. For example, bandpass filter 122A allows laser beam 114A to pass, and blocks laser beams 114B, 114C, and 114D. Similarly, bandpass filter 122D allows laser beam 114D to pass, and blocks laser beams 114A, 114B, and 114C.

Laser beams 114A, 114B, 114C, and 114D, after passing-through bandpass filters 122, are projected on reflector 126, which is configured to reflect all of the laser beams 114, even if their wavelengths are different from each other. The reflected laser beams 114 will be further projected on other bandpass filters that are configured not to allow them to pass, and are reflected again. The reflection may occur back-and-forth, until the laser beams 114 are projected into the corresponding optical fiber 112.

For example, the laser beam 114A that has passed-through bandpass filter 122A will be reflected sequentially by reflector 126, bandpass filter 122B, reflector 126, bandpass filter 122C, reflector 126, and bandpass filter 122D, and projected into optical fiber 122.Tthe laser beam 114B that has passed-through bandpass filter 122B will be reflected sequentially by reflector 126, bandpass filter 122C, reflector 126, and bandpass filter 122D, and projected into optical fiber 122. The laser beam 114C that has passed-through bandpass filter 122C will be reflected sequentially by reflector 126 and bandpass filter 122D, and projected into optical fiber 122. The laser beam 114D that has passed-through bandpass filter 122D will be projected into optical fiber 122 directly.

Through the structure in FIG. 10, the laser beams 114A, 114B, 114C, and 114D, which passes one column of grating couplers 48 and one column of micro lenses 84, are merged into one optical fiber 112. The laser beams 114 corresponding to multiple columns of grating couplers 48 and multiple columns of micro lenses 84 are merged into a plurality of (a row of) optical fibers 112 as shown in FIG. 9.

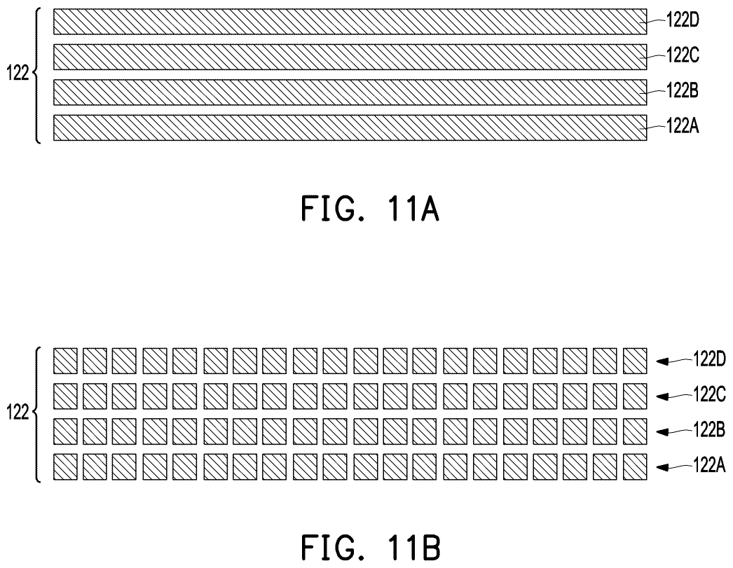

FIG. 11A illustrates an example bandpass filter 122 in accordance with some embodiments. The bandpass filter 122 includes a plurality of elongated bandpass filters 122A, 122B, 122C, and 122D, each for passing the laser beam with one characteristic wavelength, and blocking the laser beams with other characteristic wavelengths. The laser beams projected out of all of micro lenses 84 that are in the same row may be projected to the same bandpass filter 122A, 122B, 122C, or 122D. The length of bandpass filters 122A, 122B, 122C, and 122D is great enough to receive the laser beams passing through an entire row of grating couplers 48 and an entire row of micro lenses 84.

FIG. 11B illustrates an example bandpass filter 122 in accordance with alternative embodiments. These embodiments are similar to the embodiments in FIG. 11A, except the long bandpass filters 122A, 122B, 122C, and 122D in FIG. 11A are separated into a bandpass filter array (also denoted as bandpass filter array 122), which may have the same number of rows and the same number of columns as grating coupler array 48 and micro lenses array 84. The bandpass filter array 122 also has a one-to-one correspondence to the grating coupler array 48 and micro lenses array 84. Accordingly, a laser beam transported into one grating coupler will be projected to the corresponding micro lens 84, and projected to the corresponding bandpass filter 122 in the bandpass filter array 122. For example, a laser beam 114C corresponding to the grating coupler 48-3-1 in the third column of grating coupler array 48 may pass-through the micro lens 84-3-1 in the third column of micro lens array 84, and is projected into optical fiber 122-3 (FIG. 9).

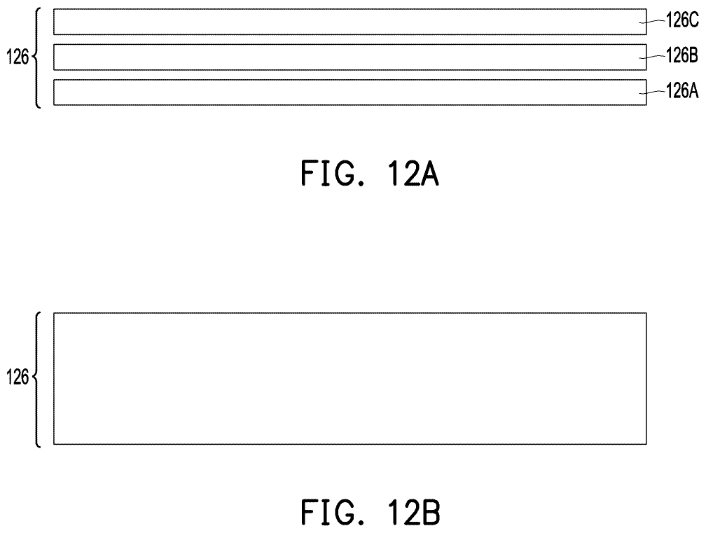

FIGS. 12A and 12B illustrate the reflector 126 in accordance with some embodiments. In FIG. 12A, the reflector 126 are separated into three elongated strips 126, 126B, and 126C, each for reflecting the laser beam passing through or reflected by band pass filters 122A, 122B, and 122C, as can be realized from FIG. 9. FIG. 12B illustrates an embodiment in which the reflector 126 is a single piece that is large enough so that all laser beams passing through or reflected by band pass filters 122A, 122B, and 122C will be projected on and reflected by the reflector 126. Reflector 126 may also include a plurality of separated reflecting elements, for example, with 3×20 elements.

It is appreciated that the structure shown in FIG. 10 may be used for the laser beams transported in a reversed direction than discussed above. The mechanism is essentially the same as discussed referring to FIG. 8, except the propagating direction of laser beams is reversed.

For example, a laser beam comprising merged laser beam 114A, 114B, 114C, and 114D may be transported using optical fiber 112-1, and projected on bandpass filter 122D. The laser beam 114D passes through bandpass filter 122D. The laser beams 114A, 114B, and 114C are reflected by bandpass filter 122D and reflector 126, and projected onto bandpass filter 122C.

The laser beam 114C then passes through bandpass filter 122C. The laser beams 114A and 114B are reflected by bandpass filter 122C and reflector 126, and projected onto bandpass filter 122B. The laser beam 114B passes through bandpass filter 122B. The laser beam 114A is reflected by bandpass filter 122B and reflector 126, and passes through bandpass filter 122A. Laser beams 114A, 114B, 114C, and 114D are reflected by reflector 120 to micro lenses 84-1-1, 84-2-1, 84-3-1, and 84-4-1, respectively, and then propagated to grating couplers 48.

FIG. 13 illustrates the operation of the laser beams 114A, 114B, 114C, and 114D projected out of one column of micro lenses 114, which is assumed to be micro lenses 84-1-1, 84-2-1, 84-3-1, and 84-4-1. This embodiment is similar to the embodiments in FIG. 10, except that the laser beams 114A, 114B, 114C, and 114D are merged into more than one optical fiber 112. For example, laser beams 114A and 114B are merged into optical fiber 112A, and laser beams 114C and 114D are merged into optical fiber 112B. The operation may be realized from the discussion referring to FIG. 10.

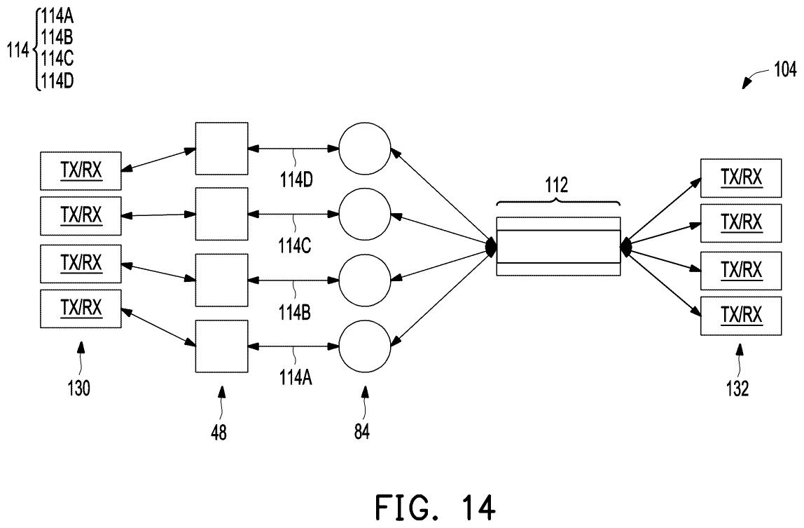

FIG. 14 illustrates a schematic view of the operation of the package 104 in accordance with some embodiments. The illustrated portion corresponds to one column of grating couplers 48, one column of micro lenses 84, and one optical fiber 112. Transceivers 130 in the photonic engine and the transceivers 132 on the far end of the optical fiber 112 are used to transmit or receive signals. The one-to-one correspondence of grating couplers 48 and micro lenses 84 is illustrated. The merge of the laser beams 114A, 114B, 114C, and 114D is illustrated. Also, the laser beams 114A, 114B, 114C, and 114D are shown using double-ended arrows, indicating that the structure is configured to merge the laser beams 114 in the photonic engine into an optical fiber, and transmitted through the optical fiber, or in a reversed direction.

The embodiments of the present disclosure have some advantageous features. By using a plurality of grating couplers having different structures and different characteristic wavelengths, a wide bandwidth can be covered by the combination of the plurality of grating couplers. The resulting optical package has reduced loss for the wide bandwidth. The bandwidth may be increased by simply adding more grating couplers.

In accordance with some embodiments of the present disclosure, a method comprises receiving a photonic engine comprising a photonic die comprising a plurality of grating couplers; and a plurality of micro lenses attached to the photonic die, wherein the plurality of grating couplers and the plurality of micro lenses are configured to be optically inter-coupled in a one-to-one correspondence; and attaching a fiber assembly unit to the photonic engine, wherein the fiber assembly unit comprises an optical fiber; and a laser merging unit configured to optically inter-couple the plurality of micro lenses and the optical fiber.

In an embodiment, the plurality of grating couplers are aligned as a column, and wherein the plurality of grating couplers have different structures. In an embodiment, the plurality of grating couplers have a same pitch as the plurality of micro lenses. In an embodiment, the method further comprises, after the electronic die is bonded to the photonic die, performing a gap filling process to form a gap-fill region encircling the electronic die.

In an embodiment, the method further comprises, after the gap-fill region is formed, forming a plurality of transparent regions in the gap-fill region and overlapping the plurality of grating couplers. In an embodiment, the attaching the plurality of micro lenses comprises attaching a supporting substrate over the photonic die, wherein the supporting substrate comprises the plurality of micro lenses.

In an embodiment, the fiber assembly unit comprises a plurality of bandpass filters configured to filter laser beams that have different wavelengths. In an embodiment, the fiber assembly unit comprises a first reflector configured to reflect laser beams that have been projected out of the plurality of micro lenses, wherein the laser beams are reflected by the first reflector to the plurality of bandpass filters; and a second reflector configured to reflect the laser beams that have passed through the plurality of bandpass filters.

In accordance with some embodiments of the present disclosure, a method comprises forming a photonic die comprising a plurality of grating couplers, wherein characteristic wavelengths of the plurality of grating couplers are different from each other, and the plurality of grating couplers have a first pitch; bonding an electronic die to the photonic die; forming a gap-fill region aside of the electronic die and over the photonic die; and attaching a supporting substrate to the gap-fill region, wherein the supporting substrate comprises a plurality of micro lenses, and wherein the plurality of micro lenses have a second pitch same as the first pitch.

In an embodiment, the method further comprises attaching a fiber assembly unit to the supporting substrate, wherein the fiber assembly unit is configured to merge laser beams propagated out of the plurality of grating couplers into an optical fiber in the fiber assembly unit. In an embodiment, the fiber assembly unit comprises the optical fiber; and a laser merging unit configured to optically inter-couple the plurality of micro lenses and the optical fiber. In an embodiment, the laser merging unit comprises a plurality of bandpass filters configured to filter laser beams that have different wavelengths.

In an embodiment, the fiber assembly unit further comprises a first reflector configured to reflect laser beams projected from the plurality of micro lenses to the plurality of bandpass filters; and a second reflector configured to reflect the laser beams passed through the plurality of bandpass filters. In an embodiment, the plurality of grating couplers comprise a grating coupler array comprising a plurality of rows and a plurality columns, wherein grating couplers in a same row of the plurality of rows have a same structure. In an embodiment, grating couplers that are in each row of the plurality of rows have a structure different from structures of the grating couplers in other rows of the plurality of rows.

In accordance with some embodiments of the present disclosure, a structure comprises a photonic die comprising a plurality of grating couplers, wherein the plurality of grating couplers have a first pitch, and the plurality of grating couplers have structures different from each other; an electronic die signally coupled to the photonic die; a dielectric region encircling the electronic die and over the photonic die; a supporting substrate over the dielectric region, wherein the supporting substrate comprises a plurality of micro lenses, and wherein the plurality of micro lenses have a second pitch same as the first pitch; and a fiber assembly unit comprising an optical fiber that is configured to receive laser beams propagated from the plurality of micro lenses.

In an embodiment, characteristic wavelengths of the plurality of grating couplers are different from each other. In an embodiment, the plurality of grating couplers are aligned as a column, and the photonic die comprises a grating coupler array comprising a plurality of columns that are same as the column. In an embodiment, the plurality of grating couplers comprise a plurality of rows, and wherein grating couplers in each row of the plurality of rows have structures same as each other. In an embodiment, the fiber assembly unit comprises a plurality of optical fibers, each configured to receive laser beams propagated from one column of grating couplers in the grating coupler array.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
receiving a photonic engine comprising:
a photonic die comprising a plurality of grating couplers; and
a plurality of micro lenses attached to the photonic die, wherein the plurality of grating couplers and the plurality of micro lenses are configured to be optically inter-coupled in a one-to-one correspondence; and
attaching a fiber assembly unit to the photonic engine, wherein the fiber assembly unit comprises:
an optical fiber; and
a laser merging unit configured to optically inter-couple the plurality of micro lenses and the optical fiber.

2. The method of claim 1, wherein the plurality of grating couplers are aligned as a column, and wherein the plurality of grating couplers have different structures.

3. The method of claim 1, wherein the plurality of grating couplers have a same pitch as the plurality of micro lenses.

4. The method of claim 1 further comprising:
bonding an electronic die over the photonic die; and
after the electronic die is bonded to the photonic die, performing a gap filling process to form a gap-fill region encircling the electronic die.

5. The method of claim 4 further comprising:
after the gap-fill region is formed, forming a plurality of transparent regions in the gap-fill region and overlapping the plurality of grating couplers.

6. The method of claim 1, wherein the attaching the plurality of micro lenses comprises attaching a supporting substrate over the photonic die, wherein the supporting substrate comprises the plurality of micro lenses.

7. The method of claim 1, wherein the fiber assembly unit comprises a plurality of bandpass filters configured to filter laser beams that have different wavelengths.

8. The method of claim 7, wherein the fiber assembly unit comprises:
a first reflector configured to reflect laser beams that have been projected out of the plurality of micro lenses, wherein the laser beams are reflected by the first reflector to the plurality of bandpass filters; and
a second reflector configured to reflect the laser beams that have passed through the plurality of bandpass filters.

9. A method comprising:
forming a photonic die comprising a plurality of grating couplers, wherein characteristic wavelengths of the plurality of grating couplers are different from each other, and the plurality of grating couplers have a first pitch;
bonding an electronic die to the photonic die;
forming a gap-fill region aside of the electronic die and over the photonic die; and
attaching a supporting substrate to the gap-fill region, wherein the supporting substrate comprises a plurality of micro lenses, and wherein the plurality of micro lenses have a second pitch same as the first pitch.

10. The method of claim 9 further comprising attaching a fiber assembly unit to the supporting substrate, wherein the fiber assembly unit is configured to merge laser beams propagated out of the plurality of grating couplers into an optical fiber in the fiber assembly unit.

11. The method of claim 10, wherein the fiber assembly unit comprises:
the optical fiber; and
a laser merging unit configured to optically inter-couple the plurality of micro lenses and the optical fiber.

12. The method of claim 11, wherein the laser merging unit comprises a plurality of bandpass filters configured to filter laser beams that have different wavelengths.

13. The method of claim 12, wherein the fiber assembly unit further comprises:
a first reflector configured to reflect laser beams projected from the plurality of micro lenses to the plurality of bandpass filters; and
a second reflector configured to reflect the laser beams passed through the plurality of bandpass filters.

14. The method of claim 9, wherein the plurality of grating couplers comprise:
a grating coupler array comprising a plurality of rows and a plurality columns, wherein grating couplers in a same row of the plurality of rows have a same structure.

15. The method of claim 14, wherein grating couplers in each row of the plurality of rows have a structure different from structures of the grating couplers in other rows of the plurality of rows.

16. A structure comprising:
a photonic die comprising a plurality of grating couplers, wherein the plurality of grating couplers have a first pitch, and the plurality of grating couplers have structures different from each other;
an electronic die signally coupled to the photonic die;
a dielectric region encircling the electronic die and over the photonic die;
a supporting substrate over the dielectric region, wherein the supporting substrate comprises a plurality of micro lenses, and wherein the plurality of micro lenses have a second pitch same as the first pitch; and
a fiber assembly unit comprising an optical fiber that is configured to receive laser beams propagated from the plurality of micro lenses.

17. The structure of claim 16, wherein characteristic wavelengths of the plurality of grating couplers are different from each other.

18. The structure of claim 16, wherein the plurality of grating couplers are aligned as a column, and the photonic die comprises a grating coupler array comprising a plurality of columns that are same as the column.

19. The structure of claim 18, wherein the plurality of grating couplers comprise a plurality of rows, and wherein grating couplers in each row of the plurality of rows have structures same as each other.

20. The structure of claim 18, wherein the fiber assembly unit comprises a plurality of optical fibers, each configured to receive laser beams propagated from one column of grating couplers in the grating coupler array.
